(19) United States
(12) Patent Application Publication
(10) Pub. No.: US 2013/0003323 A1
(43) Pub. Date: Jan. 3, 2013

(54) CONDUCTIVE GASKET HOLDER

(76) Inventor: Loc Huynh, Irvine, CA (US)

(21) Appl. No.: 13/184,783

(22) Filed: Jul. 18, 2011

Related U.S. Application Data
(60) Provisional application No. 61/502,743, filed on Jun. 29, 2011.

(51) Int. Cl. H05K 5/00; H02G 3/04

(52) U.S. Cl. 361/752; 174/68.1

(57) ABSTRACT

A gasket holder mountable to a printed circuit board and configured to isolate a conductive gasket from live electronic components and maintain the conductive gasket in an upright position under compressive pressure. The holder comprises four vertically extending walls with adjacent walls at right angles to one another. The gasket holder further including a mounting tab extending laterally from the base of one of the four walls.

### CROSS-REFERENCE TO RELATED APPLICATION

This application claims priority to provisional Application Ser. No. 61/502,743 filed Jun. 29, 2011, which application is fully incorporated herein by reference.

### FIELD

The embodiments provided herein relate generally to printed circuit boards and more particularly to a holder for a conductive gasket that makes contact between ground on the printed circuit board and a metal part in a chassis.

### BACKGROUND INFORMATION

In electronic devices such as televisions, a printed circuit or wiring board is mounted in a chassis. A conductive gasket is used to make contact between ground on the printed circuit board and a metal part in the chassis. As shown in FIG. 1, the printed circuit board 10 typically has a copper ground square 12. The ground square 12 can be formed of some other conductive material. As shown in FIG. 2, a conductive gasket 14 in the form of a rectangular cube is placed on the ground square 12. When assembled, a metal portion of the chassis holding the printed circuit board 10 compresses the conductive gasket 14 to make contact between ground on the printed circuit board 10 and the metal part on the chassis. However, because the conductive gasket 14 is not rigid and is compressive, it does not always stay upright under compressive pressure and, as a result, may come into contact with live electronic components on the printed circuit board 10.

Accordingly, it would be desirable to keep the gasket isolated from live electronic components on the printed circuit board and keep the gasket upright under compressive pressure.

### SUMMARY

The systems and methods described herein are directed to a gasket holder mountable to a printed circuit board and configured to isolate a conductive gasket from live electronic components on the printed circuit board and maintain the conductive gasket in an upright position under compressive pressure. The gasket holder comprises four vertically extending walls with adjacent walls at right angles to one another. The gasket holder further includes a mounting tab extending laterally from the base of one of the four walls. The bottom surface of the mounting tab and, optionally, the bottom edges of the four walls having an adhesive, such as double sided tape, to secure the holder to the printed circuit board.

Other systems, methods, features and advantages of the invention will be or will become apparent to one with skill in the art upon examination of the following figures and detailed description.

### BRIEF DESCRIPTION OF THE FIGURES

The details of the invention, including fabrication, structure and operation, may be gleaned in part by study of the accompanying figures, in which like reference numerals refer to like parts. The components in the figures are not necessarily to scale, emphasis instead being placed upon illustrating the principles of the invention. Moreover, all illustrations are intended to convey concepts, where relative sizes, shapes and other detailed attributes may be illustrated schematically rather than literally or precisely.

FIG. 1 depicts a perspective view of a printed circuit board with a copper ground square.

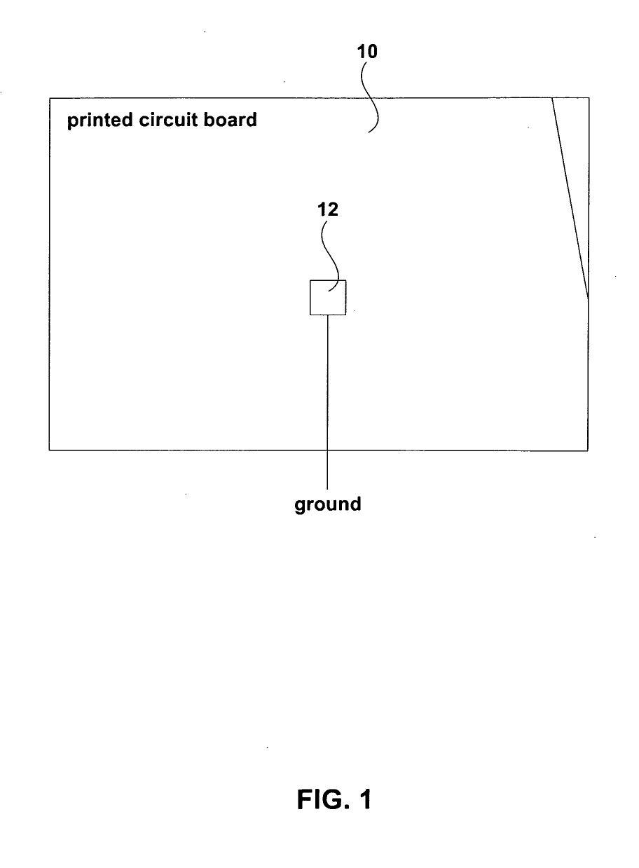

FIG. 2 depicts a perspective view of the printed circuit board in FIG. 1 with a conductive gasket mounted on the copper ground square.

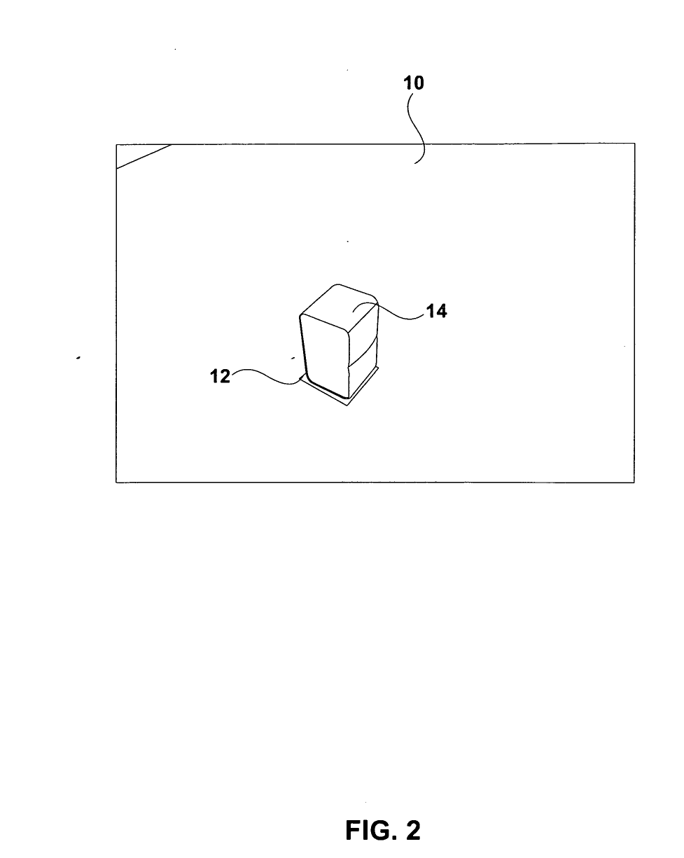

FIG. 3 depicts a perspective view of a gasket holder.

FIG. 4 depicts a perspective view of the gasket holder mounted on the printed circuit board.

FIG. 5 depicts a perspective view of the gasket holder mounted on the printed circuit board with the conductive gasket mounted therein.

FIG. 6 depicts a perspective view of the gasket holder mounted on the printed circuit board with the conductive gasket mounted therein and a partial view of the chassis.

FIG. 7 depicts a perspective view of the gasket holder mounted on the printed circuit board with the conductive gasket mounted therein and a metal portion of the chassis applying compressive pressure to the conductive gasket.

FIG. 8 depicts a detail perspective view taken along line 8-8 in FIG. 7 showing the gasket holder mounted on the printed circuit board with the conductive gasket mounted therein and a metal portion of the chassis applying compressive pressure to the conductive gasket.

### DETAILED DESCRIPTION

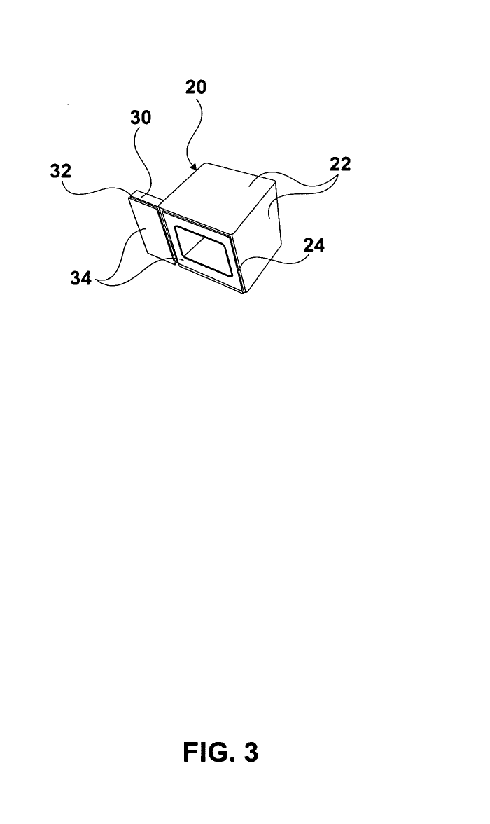

The systems and methods described herein are directed to a gasket holder mountable to a printed circuit board and configured to isolate the gasket from live electronic components on the printed circuit board and maintain the gasket in an upright position under compressive pressure. Turning to FIG. 3, the gasket holder 20 comprises four vertically extending walls 22 with adjacent walls at right angles (90°) to one another defining a volume internal thereto. The gasket holder 20 further includes a mounting tab 30 extending laterally from the base of at least one of the four walls 22. The bottom surface 32 of the mounting tab 30 and, optionally, the bottom edges 24 of the four walls 22 includes an adhesive, such as double sided tape, to secure the gasket holder 20 to the printed circuit board 10.

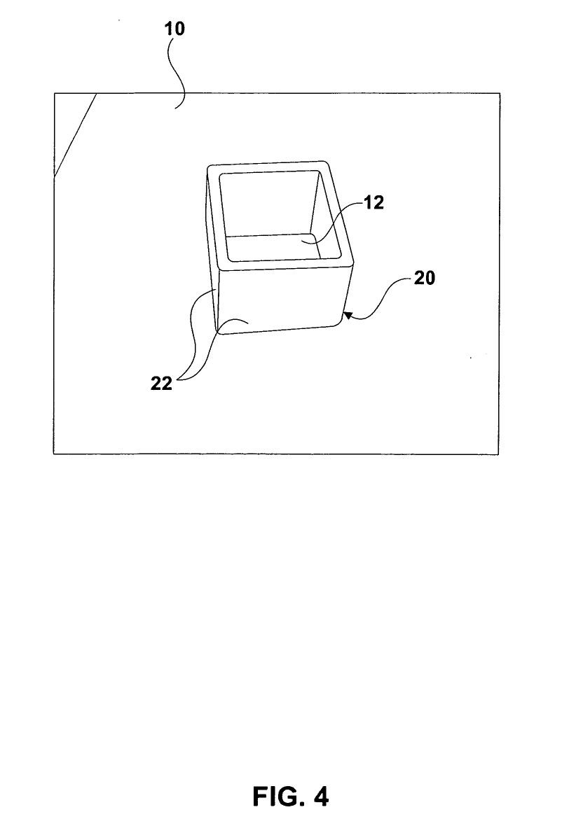

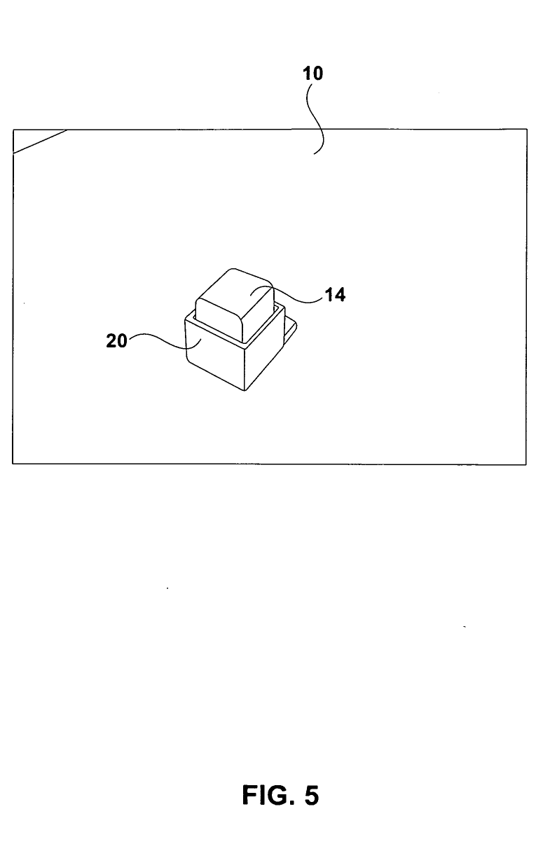

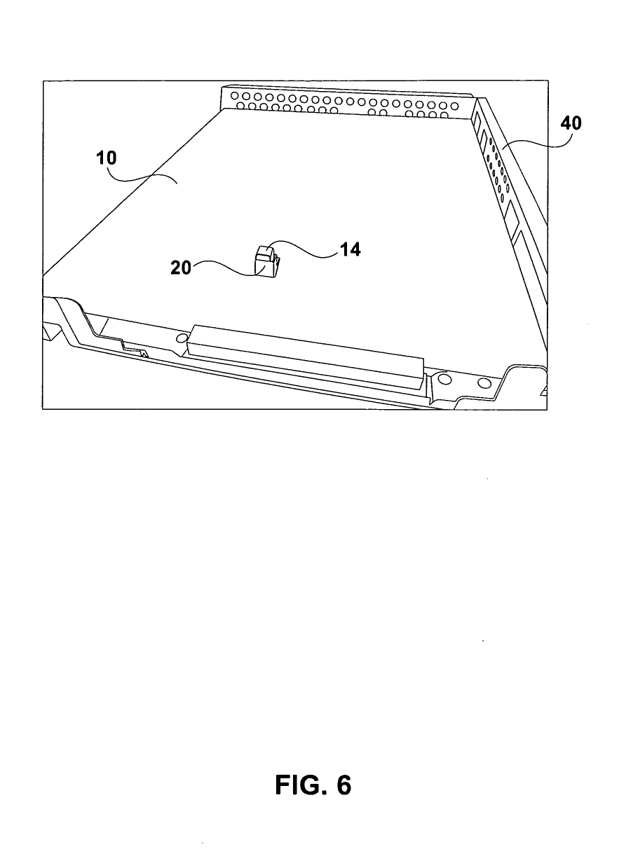

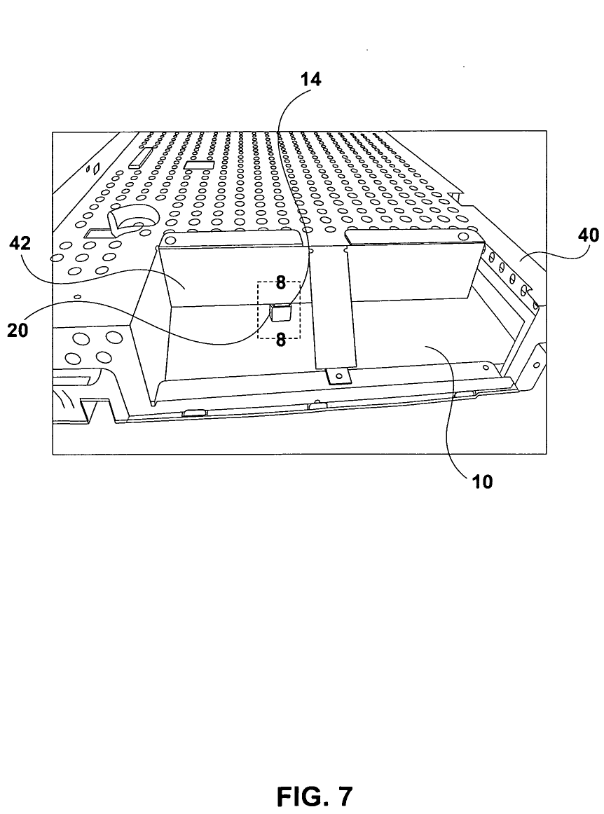

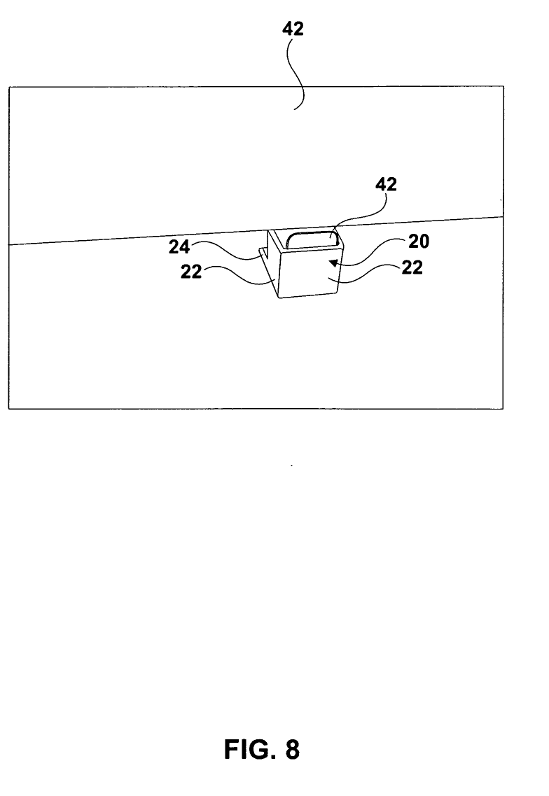

In operation, as depicted in FIGS. 4 through 8, the gasket holder 20 is secured to the printed circuit board 10, as shown in FIG. 4, with the four walls 22 surrounding the copper ground square 12 and extending vertically from the printed circuit board 10. As shown in FIG. 5, the conductive gasket 14 is received and retained within the interior of the four walls 22 of the gasket holder 20 when mounted on the copper ground square 12 of the printed circuit board 10. As depicted in FIG. 6, the printed circuit board 10 is mounted to a chassis 40 for a television or other electronic device. When fully assembled, as shown in FIGS. 7 and 8, a metal portion 42 of the chassis 40 compresses the conductive gasket 14 to make contact between ground 12 on the printed circuit board 10 and the metal portion 42 of the chassis 40. As shown, the gasket holder 20 maintains the conductive gasket 14 in an upright position under the compressive pressure of the metal portion 42 of the chassis 40 and isolates the conductive gasket 14 from live components on the printed circuit board 10.

In the foregoing specification, the invention has been described with reference to specific embodiments thereof. It will, however, be evident that various modifications and changes may be made thereto without departing from the broader spirit and scope of the invention. For example, the reader is to understand that the specific ordering and combination of process actions shown in the process flow diagrams described herein is merely illustrative, unless otherwise stated, and the invention can be performed using different or additional process actions, or a different combination or ordering of process actions. As another example, each feature of one embodiment can be mixed and matched with other features shown in other embodiments. Features and processes known to those of ordinary skill may similarly be incorporated as desired. Additionally and obviously, features may be added or subtracted as desired. Accordingly, the invention is not to be restricted except in light of the attached claims and their equivalents.

What is claimed is:

1. A television comprising
a chassis,
a printed circuit board mounted in the chassis,
a conductive gasket contacting a ground portion on the printed circuit board and a metal portion on the chassis, and
a gasket holder mountable to the printed circuit board, the gasket holder configured to isolate the conductive gasket from live electronic components on the printed circuit board and to maintain the conductive gasket in an upright position under compressive pressure from the metal portion of the chassis.

2. The television of claim 1 wherein the gasket holder comprises four vertically extending walls.

3. The television of claim 2 wherein adjacent walls of the four walls are positioned at right angles to one another.

4. The television of claim 2 wherein the gasket holder further includes a mounting tab extending laterally from the base of one of the four walls.

5. The television of claim 4 wherein a bottom surface of the mounting tab includes an adhesive to secure the gasket holder to the printed circuit board.

6. A gasket holder mountable to a printed circuit board, the gasket holder comprising
four vertically extending walls defining a volume configured to receive a gasket, and
a mounting tab extending from the base of one of the walls.

7. The gasket holder of claim 6 wherein adjacent walls of the four walls are positioned at right angles to one another.

8. The gasket holder of claim 7 wherein a bottom surface of the mounting tab includes an adhesive to secure the gasket holder to a printed circuit board.

9. The gasket holder of claim 8 wherein a bottom edge of the four walls includes an adhesive to secure the gasket holder to the printed circuit board.
